(19) United States
(12) Patent Application Publication
(10) Pub. No.: US 2017/0040557 A1
(43) Pub. Date: Feb. 9, 2017

(54) Tandem Photovoltaic Module Comprising a Control Circuit

(71) Applicant: The Board of Trustees of the Leland Stanford Junior University, Palo Alto, CA (US)

(72) Inventors: Colin Bailie, Menlo Park, CA (US); Timothy Matthew Burke, Menlo Park, CA (US); Michael David McGehee, Menlo Park, CA (US)

(21) Appl. No.: 15/229,820

(22) Filed: Aug. 5, 2016

Related U.S. Application Data
(60) Provisional application No. 62/201,238, filed on Aug. 5, 2015.

(51) Int. Cl. H01L 51/42; H02S 40/32; H01L 31/05; H01L 31/0687; H01L 31/028; H02S 40/36; H02J 3/38

(52) U.S. Cl. CPC H01L 51/4213; H02S 40/36; H02S 40/32; H02J 3/385; H01L 31/0687; H01L 31/028; H01L 31/0504

(57) ABSTRACT

A solar-cell module comprising a tandem solar cell and a controller that substantially optimizes the power output the tandem solar cell is disclosed. The tandem solar cell includes a first solar cell having a first energy bandgap and a second solar cell having a second energy bandgap, where the first and second solar cells are arranged such that light not absorbed by the first solar cell passes through it to the second solar cell to be absorbed. The controller controls an electrical parameter, such as current or voltage, of at least one of the first and second solar cells such that the electrical parameter is equal in both cells, thereby substantially optimizing the output power of the tandem solar cell.

### STATEMENT OF RELATED CASES

This case claims priority to U.S. Provisional Patent Application Ser. No. 62/201,238 filed on Aug. 5, 2015 (Attorney Docket: 146-060PR1), which is incorporated herein by reference.

### STATEMENT REGARDING FEDERALLY SPONSORED RESEARCH

This invention was made with Government support under contract DE-EE0004946 awarded by the Department of Energy. The Government has certain rights in the invention.

### FIELD OF THE INVENTION

The present invention relates to solar cells in general, and, more particularly, to tandem solar cells and solar-cell-control circuits.

### BACKGROUND OF THE INVENTION

A solar cell is device that absorbs light and converts its optical energy into electrical energy. The most common solar cell is a semiconductor diode structure having an electron-rich portion (n side) and a hole-rich (p side), which collectively define a p-n junction at the boundary between them. As photons are absorbed in the semiconductor material, their energy generates free-carrier pairs (i.e., electron-hole pairs) on both sides of the p-n junction. Liberated holes are attracted to the n side of the junction by a large electric field associated with the p-n junction, while liberated electrons are attracted to the p side of the junction, thereby creating a significant voltage potential across the solar cell. When a load (e.g., a light bulb) is connected across the solar cell to form a circuit, an electric current will conduct through the circuit providing electrical power to the load when the solar cell is illuminated.

The energy band gap (E_{G}) of its material determines the wavelengths of light absorbed by a solar cell. Photons having energy less than E_{G} interact only weakly with the semiconductor material and, generally, pass through as if the semiconductor were transparent. Photons having energy greater than E_{G}, however, are absorbed by the semiconductor material and generate free-carrier pairs.

The energy gap of its material also determines, and fundamentally limits, the efficiency with which a single-junction solar cell converts photons into electrical energy. For silicon (E_{G}=1.12 eV), the most ubiquitous solar cell material in the market, this theoretical efficiency limit is 29%, with a practical efficiency limit that is in the mid-20% range. Advances in silicon-cell architecture technology have enabled present-day silicon solar cells to approach this practical efficiency limit; as a result, the cost advantages that can be gained by further improvements to silicon solar cell efficiency are limited.

In order to derive additional cost-reduction for solar-cell technology, therefore, concepts beyond straight-forward improvements in single-junction solar cell efficiency are needed.

### SUMMARY OF THE INVENTION

The present invention enables improvement in solar-conversion efficiency and cost without some of the disadvantages of the prior art. Embodiments of the present invention include a tandem solar cell and a controller that enables independent control over an electrical parameter (i.e., voltage, current, or power) of each constituent solar cell in the tandem solar cell configuration. As a result, the present invention enables operation of a tandem solar cell in which substantially peak performance of each solar cell is maintained. The present invention therefore, mitigates problems inherent to tandem solar cells, such as: deviation of the solar spectrum due to weather changes or improper location; unequal device degradation over time, and the like. Further, embodiments of the present invention are afforded advantages over the prior art, such as: providing controller functionality as a maximum power-point tracker; simplified module binning for determining appropriate modules for sale, where the binning is based on power output rather than current output.

An illustrative embodiment of the present invention is a solar cell module comprising a tandem solar cell and a controller. The tandem solar cell includes monolithically integrated top and bottom cells, where the top cell is based on a metal-halide-perovskite material and the bottom cell is based on silicon. In some embodiments, the top and bottom cells are not monolithically integrated but are, instead, physically stacked to form a hybrid combination. In some embodiments, a photovoltaic material other than a metal-halide-perovskite material is used in the top cell. In some embodiments, a photovoltaic material other than silicon is used in the bottom cell.

In the illustrative embodiment, the controller is a DC-DC converter based on a buck-regulator architecture, where the controller controls the output current of the top cell to match the output current of the bottom cell.

In some embodiments, the controller is a different type of DC-DC converter. In some embodiments, the controller controls the output current of the bottom cell such that it substantially matches the output current of the top cell. In some embodiments, the controller controls the output current of both cells. In some embodiments, the top and bottom cells are electrically connected in parallel and the controller is arranged to control the output voltage of one or both of the top and bottom cells. In some embodiments, the controller also functions as an emergency shutoff device that disables one or more tandem solar cells when an electrical parameter, such as maximum voltage, current, or power, is exceeded.

An embodiment of the present invention is a solar-cell module comprising: a first solar cell having a first energy bandgap; a second solar cell having a second energy bandgap, the second solar cell being electrically coupled with the first solar cell; and a controller that is operably coupled with the first solar cell and the second solar cell such that the controller is operative for controlling an electrical parameter of at least one of the first solar cell and the second solar cell, the electrical parameter being at least one of current, voltage, and power; wherein the first solar cell and second solar cell are arranged such that (1) the first solar cell is operative for absorbing a first portion of a first light signal and passing a second portion of the first light signal to the second solar cell and (2) the second solar cell is operative for absorbing the second portion of the first light signal.

Another embodiment of the present invention is a solar-cell module comprising: a first solar cell comprising a metal-halide perovskite; a second solar cell comprising silicon; and a controller that is that is operative for equalizing an electrical parameter of the first solar cell and the second solar cell, the electrical parameter being at least one of current, voltage, and power; wherein the first solar cell and second solar cell are arranged such that (1) the first solar cell is operative for absorbing a first portion of a first light signal and passing a second portion of the first light signal to the second solar cell and (2) the second solar cell is operative for absorbing the second portion of the first light signal.

Yet another embodiment of the present invention is a method for controlling an electrical parameter of a first solar cell having a first electrical bandgap and a second solar cell having a second electrical bandgap, wherein the first solar cell and second solar cell collectively define a tandem solar cell, the method comprising: providing the tandem solar cell such that (1) the first solar cell is operative for absorbing a first portion of a first light signal and passing a second portion of the first light signal to the second solar cell and (2) the second solar cell is operative for absorbing the second portion of the first light signal; providing a controller than is operatively coupled with the tandem solar cell; measuring a first electrical parameter of the tandem solar cell, wherein the first electrical parameter is selected from the group consisting of current, voltage, and power; and controlling a second electrical parameter of at least one of the first solar cell and the second solar cell based on the measured first electrical parameter, wherein the second electrical parameter is selected from the group consisting of current, voltage, and power.

### BRIEF DESCRIPTION OF THE DRAWINGS

FIG. 1 depicts a schematic diagram of a portion of a solar cell module in accordance with an illustrative embodiment of the present invention.

FIG. 2 depicts a schematic drawing of controller 104 as configured within module 100 in accordance with the illustrative embodiment of the present invention.

FIG. 3 depicts operations of a method for controlling an electrical parameter of a solar cell included in a tandem solar cell in accordance with the illustrative embodiment.

FIG. 4 depicts a solar module comprising a plurality of top solar cells and a plurality of bottom solar cells in accordance with a first alternative embodiment of the present invention.

FIG. 5 depicts a schematic drawing of an example of an alternative controller configuration for use with top and bottom cells that are electrically connected in parallel in accordance with the present invention.

FIG. 6 depicts a schematic drawing of another alternative controller configuration in accordance with the present invention.

### DETAILED DESCRIPTION

It is an aspect of the present invention that a solar-cell module having improved efficiency compared to prior-art solar cells is enabled by (1) the use of a tandem solar-cell configuration having top and bottom cells, where the top and bottom cells are based on materials having different energy band gaps, and (2) by providing appropriate control over the power output of each of its constituent solar cells.

One skilled in the art will recognize that the energy of a photon is inversely proportional to its wavelength (Eₚ=hc/Δ, where Eₚ is photon energy, h is Planck's constant, c is the speed of light, and λ is wavelength); therefore, longer-wavelength light (e.g., red light) has lower photon energy than shorter-wavelength light (e.g., blue light).

Embodiments of the present invention comprise a stacked cell structure (referred to as a “tandem solar cell”) having a top photovoltaic portion and a bottom photovoltaic portion, where the two portions are characterized by two different energy band gaps. The top portion is made of a first material having a relatively higher energy band gap and the bottom portion is made of a second material having a relatively lower energy band gap, such that the stacked cell structure includes two p-n junctions. As a result, when light is incident on the stacked cell structure, high-energy photons in the light are absorbed in the top photovoltaic portion while photons having energy lower than the higher energy band gap pass through the top photovoltaic portion to the bottom photovoltaic portion. Photons having energy between the energy band gaps of the two materials are then absorbed in the bottom photovoltaic portion. The present invention, therefore, enables a broad spectrum of light to be absorbed in a solar-cell structure, thereby improving energy-conversion efficiency beyond the single-junction efficiency limit.

Tandem solar-cell configurations in accordance with the present invention enable a reduction in the thermalization loss of high-energy photons. For a silicon-based tandem solar cells (i.e., a tandem solar cell whose bottom photovoltaic portion is silicon, which has an E_{G} of 1.12 eV), the fundamental efficiency limit can be as high as approximately 39%, depending on the E_{G} of the material of the top photovoltaic portion. In accordance with the present invention, improved efficiency is further enabled by employing an active, self-controlled circuit to correct for mismatches between the output performance of the top and bottom solar cells thereby enabling substantially optimal power output from each solar cell.

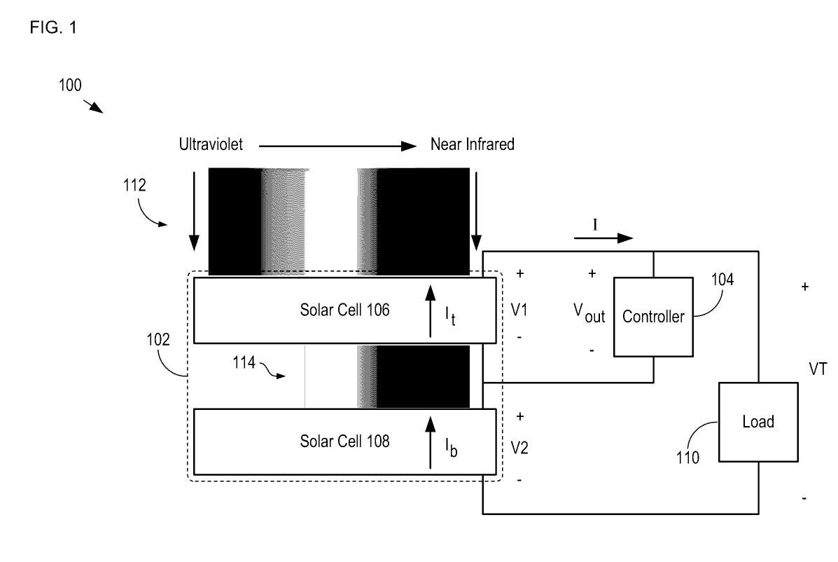

FIG. 1 depicts a schematic diagram of a portion of a solar cell module in accordance with an illustrative embodiment of the present invention. Module 100 comprises tandem solar cell 102 and controller 104. Tandem solar cell 102 includes solar cells 106 and 108, which are arranged in a tandem arrangement. Module 100 is electrically connected with load 110 to form a complete electrical circuit.

Solar cell 106 is a metal-halide perovskite-based photovoltaic cell comprising methylammonium-lead(II)-iodide perovskite (CH₃NH₃PbI₃), which has a 1.61 eV band gap.

Solar cell 108 is a silicon-based photovoltaic cell comprising crystalline silicon (c-Si), which has a 1.12 eV band gap.

Although the illustrative embodiment comprises a tandem solar cell that includes a metal-halide perovskite-based photovoltaic cell and a silicon-based photovoltaic cell, it will be clear to one skilled in the art, after reading this Specification, how to specify, make, and use alternative embodiments in which a solar-cell module includes any suitable photovoltaic material in one or both of solar cells 106 and 108. Materials suitable for use in a solar cell of a tandem solar cell configuration in accordance with the present invention include, without limitation, copper indium gallium selenide, II-VI compound semiconductors, III-V compound semiconductors, silicon compounds (e.g., silicon germanium, silicon carbide, etc.), and the like.

Solar cells 106 and 108 are monolithically integrated, as described by Mailoa, et al., in “A 2-terminal perovskite/silicon multijunction solar cell enabled by a silicon tunnel junction,” Appl. Phys. Lett., Vol. 106, 121105 (2015), which is incorporated herein by reference. It should be noted, however, that in some embodiments of the present invention, improved efficiency is obtained with a tandem configuration wherein solar cells 106 and 108 are mechanically stacked, as described by Bailie, et al., in “Semi-transparent perovskite solar cells for tandems with silicon and CIGS,” Energy Environ. Sci., Vol. 8, pp. 956-963 (2015), which is also incorporated herein by reference.

Solar cells 106 and 108 are monolithically integrated such that an inter-band tunnel junction is included to facilitate electron tunneling from the electron-selective contact of the perovskite solar cell into the p-type emitter of the silicon solar cell. In some embodiments, an inter-band tunnel junction is not included in module 100.

As discussed above, tandem solar cell 102 receives light 112, which has a wavelength spectrum that spans the range from ultraviolet to near infrared. By virtue of its higher E_{G}, solar cell 106 absorbs only the higher energy portion of the incoming light (i.e., the shorter-wavelength portion) and converts the optical energy in the absorbed light into electrical energy such that voltage V1 is developed across solar cell 106. The remainder of light 112 is passed to solar cell 108 as light signal 114. Solar cell 108 absorbs substantially all of light signal 114 and develops voltage V2. As a result, tandem solar cell 102 develops voltage VT (which equals V1+V2) across load 110 and provides output current, I.

Solar cells 106 and 108 are electrically connected in series, which imposes a physical constraint that the current, I, running through each cell must be the same. In some instances, however, there is a difference in the architecture of the cell, the intensity of light 112 that hits tandem solar cell 102, and/or the spectrum of light 112. As a result, the current generated by one of the cells is not exactly the same as the current that would be generated by the other cell. The total current of the tandem configuration, therefore, becomes limited by the solar cell that produces less current. This is a mismatch condition that limits the overall efficiency of tandem solar cell 102, since part of the power that could have been produced by the non-limiting cell is lost due to the current matching requirement. In practice, it is typically very difficult to closely match the current output solar cells 106 and 108 under typical conditions. Further, it is impossible to do so throughout each day and year since the wavelength spectrum of the light generated by the sun changes throughout the day and year.

Controller 104 is a DC-DC converter that is operatively connected with tandem solar cell 102 such that the controller enables operation of each of solar cells 106 and 108 at optimal power regardless of internal or external stressors. Controller 104 includes an active self-controlled circuit that corrects for a mismatch between solar cells 106 and 108 due to such stressors. In the illustrative embodiment, controller 104 enables control over the magnitude of the current output of solar cell 106 (i.e., the limiting cell) as necessary to match the current output of solar cell 108, improving overall efficiency. The active circuit continually checks for mismatch conditions and adjusts the DC/DC converter so that the two solar cells are always current-matched, thereby improving overall efficiency.

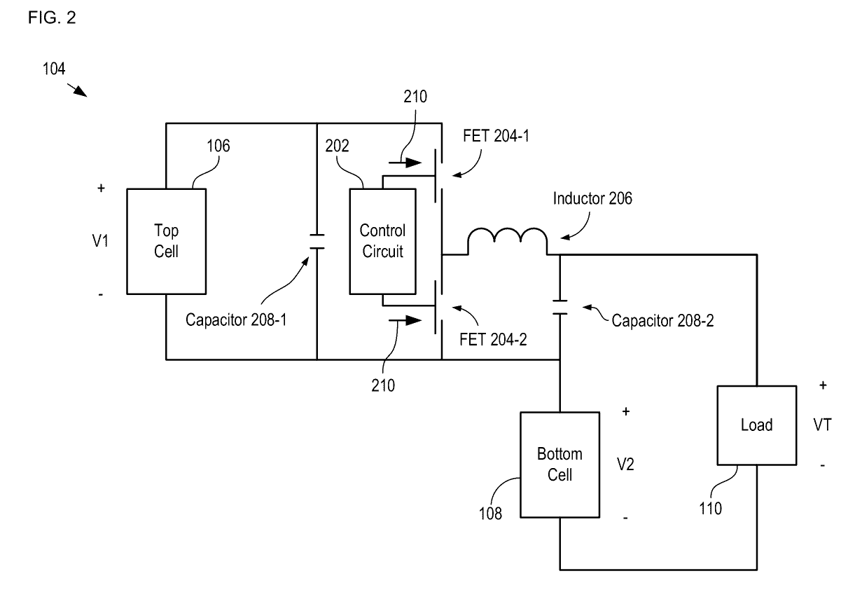

FIG. 2 depicts a schematic drawing of controller 104 as configured within module 100 in accordance with the illustrative embodiment of the present invention. Controller 104 is a DC-DC converter configured as a synchronous buck regulator architecture that includes control circuit 202, field-effect transistors (FETs) 204-1 and 204-2, inductor 206, and capacitors 208-1 and 208-2. Controller 104 is operatively coupled with the top cell of a tandem solar cell (i.e., solar cell 106). As a result, controller 104 enables the current output of solar cell 106 to be independently controlled so that it always matches the current output of solar cell 108.

Capacitors 208-1 and 208-2 are conventional capacitors having a capacitance within the range of approximately 10 microfarads to approximately 1000 microfarads.

Inductor 206 is a conventional inductor having an inductance within the range of approximately 10 microhenries to approximately 100 microhenries.

One skilled in the art will recognize, after reading this Specification, that the design of controller 104 and the values for capacitors 208-1 and 208-2 and inductor 206 are merely exemplary and that myriad alternative designs and component values can be used without departing from the scope of the present invention.

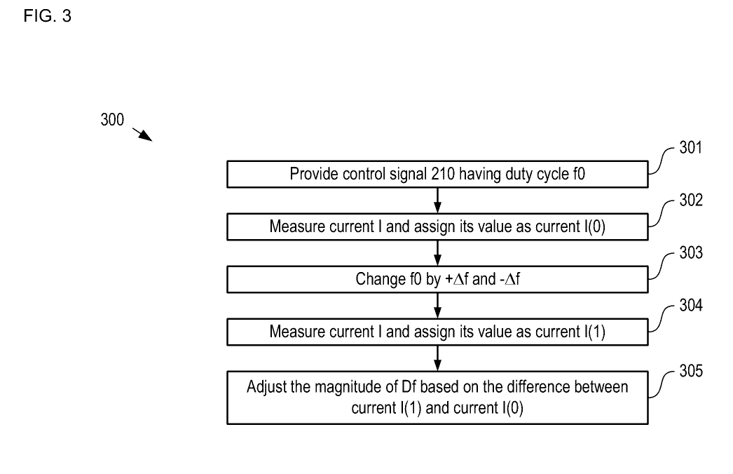

FIG. 3 depicts operations of a method for controlling an electrical parameter of a solar cell included in a tandem solar cell in accordance with the illustrative embodiment. Method 300 is described herein with continuing reference to FIGS. 1 and 2. In the depicted example, method 300 senses the condition of current matching between solar cell 106 and solar cell 108 and controls the duty cycle of the DC/DC converter to keep the difference between the solar-cell currents within an acceptable error.

Method 300 begins with operation 301, wherein control circuit 202 provides control signal 210 to FETs 204-1 and 204-2.

Each of FETs 204-1 and 204-2 is a conventional field-effect transistor that is configured to operate as a low-resistance, electronically controlled switch.

Control signal 210 alternates opening the FETs with duty cycle f0. The fraction of the time FET 204-1 is conducting determines the ratio of the output voltage of the DC/DC converter to the input voltage (i.e., the voltage on solar cell 106). One skilled in the art will recognize, after reading this Specification, that the operation of control circuit 202 is substantially independent of frequency and that the frequency of control signal 210 can be any suitable frequency.

One skilled in the art will recognize, based on the conservation of energy, that a reduction in the output voltage, V1, of solar cell 106 gives rise to an increase in the output current of solar cell 106. Further, at every duty cycle, the power output of solar cell 106 must equal the power output of the DC/DC converter (i.e., controller 104), minus small losses in the switching circuitry. As a result, for solar cell 106 operating at voltage V1 and top current Iₜ, and solar cell 108 producing bottom current I_{b} and voltage V2 with I_{b}>Iₜ, controller 104 provides output voltage, Vₒᵤₜ, as:

$${V}_{out} = V 1 \frac{{I}_{t}}{{I}_{b}} .$$

Since voltages add in series, the total output voltage, VT, of tandem solar cell 102 is given by:

$$VT = V 2 + V 1 \frac{{I}_{t}}{{I}_{b}} .$$

At operation 302, controller 104 measures current I and stores its value as current I(0). In the depicted example, the magnitude of I is determined by measuring the voltage drop across inductor 206. In some embodiments, the magnitude of I is measured in a different manner, such as by monitoring the voltage drop across a resistor through which the current, I, flows.

At operation 303, controller 104 changes the duty cycle of control signal 210 to f1. Duty cycle f1 differs from duty cycle f0 by +Δf and −Δf.

At operation 304, controller 104 measures current I and stores its value as current I(1).

At operation 305, controller 104 compares currents I(1) and I(0) and adjusts the duty cycle based on the difference. If the difference is positive and exceeds a threshold value, controller increases Δf. If the difference is negative and exceeds the threshold value, controller 104 decreases Δf. If the difference is less than the threshold value, controller does not change Δf and waits for another sampling interval.

Method 300 enables determination of a substantially optimal duty cycle, which is reached when a further increase of the duty cycle causes I to decrease and a decrease of the duty cycle causes no change in I. When neither increasing nor decreasing the duty cycle has an effect on current I, solar cell 106 is producing too much current and the duty cycle is increased. If, on the other hand, an increase in the duty cycle gives rise to a decrease in the current I and a decrease in the duty cycle increases the current, then the duty cycle is decreased.

As a result, method 300 substantially ensures that solar cells 106 and 108 are current matched. It controls the output voltage of solar cell 106 (and correspondingly controls its current, Iₜ) to achieve and maintain a matching condition. Since very little power is lost in a well-designed DC-DC converter (<5% of the top cell's power output), the present invention effectively mitigates the problem of current mismatch in tandem solar cells.

In some embodiments, controller 104 is operatively coupled with the bottom cell of a tandem solar cell. In some of these embodiments, controller 104 includes a boost regulator that enables a decrease in the output current of solar cell 108 and an increase in V2 so that the power output of solar cell 108 matches that of solar cell 106.

In some embodiments, controller 104 is configured to positively or negatively change the voltage of one or both of the constituent solar cells of a tandem solar cell. In some embodiments, controller 104 is configured to control the output power of one or both of the constituent solar cells of a tandem solar cell.

In some embodiments, multiple top cells (connected in either parallel or series or a combination of the two) and multiple bottom cells (connected in either parallel or series or a combination of the two) are operatively coupled with a single controller—either in series or parallel. In some embodiments, multiple cells are first connected in series and then those clusters of cells are connected in parallel.

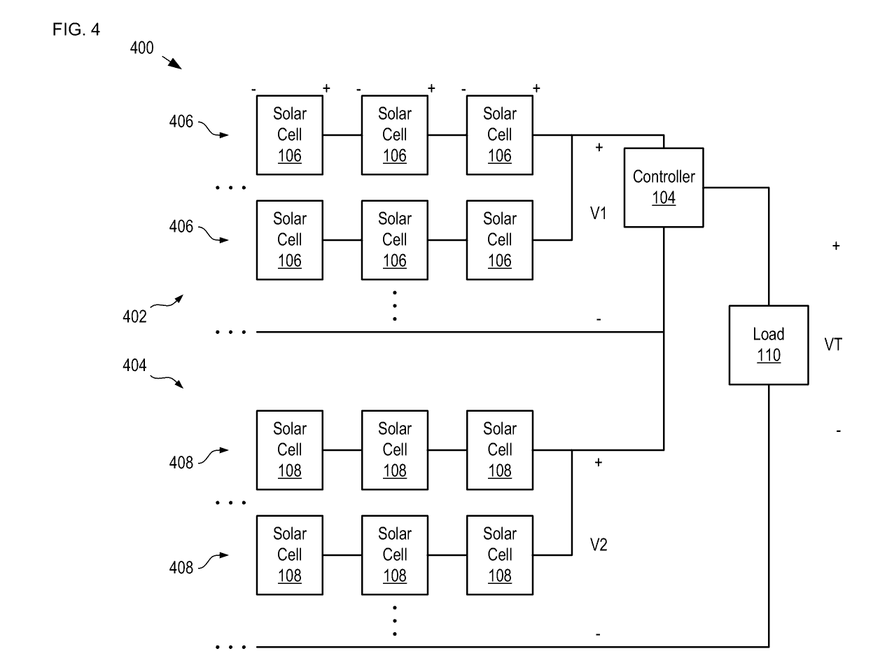

FIG. 4 depicts a solar module comprising a plurality of top solar cells and a plurality of bottom solar cells in accordance with a first alternative embodiment of the present invention. Module 400 includes top cell array 402 and bottom cell array 404, which are operatively coupled with controller 104 and load 110.

Top cell array 402 includes a plurality of solar cells 106. The plurality of solar cells 106 are arranged to define a plurality of strings 406, within which the solar cells are electrically connected in series. Strings 406 are electrically connected in parallel to collectively define top cell array 402.

In similar fashion, bottom cell array 404 includes a plurality of solar cells 108. The plurality of solar cells 108 are arranged to define a plurality of strings 408, within which the solar cells are electrically connected in series. Strings 408 are electrically connected in parallel to collectively define bottom cell array 404.

Top cell array 402 and bottom cell array 404 are electrically coupled with controller 104 and load 110 as described above and with respect to FIGS. 1-3.

In some embodiments, controller 104 includes circuitry operative for enabling additional regulation tasks, such as disabling a solar cell (by, for example, opening both of FETs 204-1 and 204-2) or solar panel if a maximum voltage is reached and/or a current limit is exceeded.

In some embodiments, solar cells 106 and 108 are electrically connected in parallel and controller 104 controls the output voltage of one or both of the solar cells such that their output voltages are equal.

It should be noted that, by combining a controller with a tandem solar cell, embodiments of the present invention are afforded significant advantages over the prior art, including enabling substantially peak performance of each solar cell to be maintained by enabling correction of:
i. an average deviation of the solar spectrum from AM1.5G conditions due to deployment in a location with larger or smaller average air mass coefficient; or
ii. a temporal deviation of the solar spectrum from average conditions due to daily/seasonal weather changes such as overcast days or sunrise/sunset; or
iii. a change in the relative portion of light signal 112 absorbed by each of solar cells 106 and 108 due to an angular deviation of the angle of incidence of the sun on module 100;
iv. a mismatch in the degradation of solar cells 106 and 108 (e.g., due to aging, etc.); or
v. a temporary or permanent change of the optical bandgap of the top or bottom cell during operation (e.g., due thermal conditions, etc.)
vi. any combination of i, ii, iii, iv, and v.

It should be further noted that the inclusion of controller 104 enables additional functionality for a tandem solar cell module, such as operation as a maximum-power-point tracker for one or both of solar cell 106 and 108 (i.e., whichever solar cell to which the controller is operatively coupled).

Still further, employing controller 104 simplifies the binning of solar-cell modules based on power output rather than current output. One skilled in the art will recognize that, in many cases, power output is a more useful metric to describe the operation of a module and to bin a solar-cell module for sale.

One skilled in the art will recognize, after reading this Specification, that the DC-DC converter arrangement described above and with respect to FIG. 2 is merely one example of a controller that can be used without departing from the scope of the present invention. As discussed above, in some embodiments, the top and bottom cells are electrically connected in parallel and the controller is arranged to control the output voltage of one or both of the top and bottom cells.

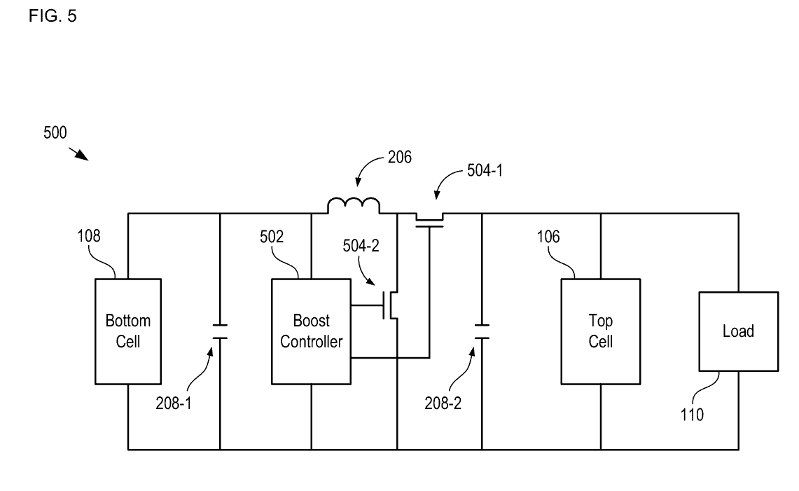

FIG. 5 depicts a schematic drawing of an example of an alternative controller configuration for use with top and bottom cells that are electrically connected in parallel in accordance with the present invention. Module 500 includes top cell 106, bottom cell 108, controller 502, MOSFETs 504-1 and 504-2, inductor 206, and capacitors 208-1 and 208-2.

Boost controller 502 is a step-up converter that operates as a DC-DC power converter. Boost controller 502 is configured such that it controls the voltage of bottom cell 108 so that it substantially matches the voltage of top cell 106.

Each of MOSFETs 504-1 and 504-2 is a conventional metal-oxide-semiconductor field-effect transistor that is configured to operate as a low-resistance, electronically controlled switch. MOSFETs 504-1 and 504-2 are analogous to FETs 204-1 and 204-2 described above and with respect to FIG. 2.

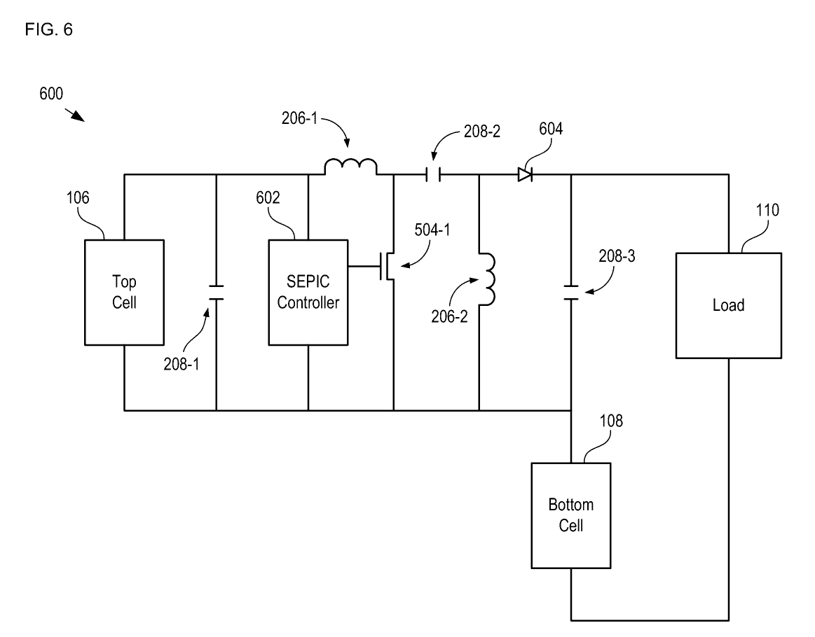

FIG. 6 depicts a schematic drawing of another alternative controller configuration in accordance with the present invention. Module 600 includes top cell 106, bottom cell 108, controller 602, MOSFET 504-1, inductors 206-1 and 206-2, capacitors 208-1, 208-2, and 208-3, and diode 604. In module 600, the cells of tandem solar cell 102 are electrically connected in series; however, it will be clear to one skilled in the art, after reading this Specification, how to specify, make, and use alternative embodiments wherein module 600 includes a tandem solar cell that is electrically connected in parallel.

Controller 602 is a single-ended primary-inductor converter (SEPIC) DC-DC controller having an output voltage that can be greater than, less than, or equal to the voltage at its input. Controller 602 controls the current through top cell 106 based on the current flow through inductor 206-1. In some embodiments, module 600 includes a shunt resistor that is electrically connected in series with load 110 and controls the current through top cell 106 based on the voltage drop across this shunt resistor.

In the depicted example, controller 602 is electrically connected with top cell 106 such that it controls the current through the top cell to match that of bottom cell 108. One skilled in the art will recognize after reading this Specification, however, that controller 602 can be electrically connected and controlled within module 600 such that it can control either current flow or voltage. As a result, it will be clear, after reading this Specification, that embodiments wherein controller 602 controls the current flow through top cell 106, or bottom cell 108, or the voltage across either of the top or bottom cell are all within the scope of the present invention. Furth, in some embodiments, each of the top cell and bottom cell is electrically connected with a controller such that its current (or voltage) is actively controlled.

It is to be understood that the disclosure teaches just some embodiments in accordance with the present invention and that many variations of the invention can easily be devised by those skilled in the art after reading this disclosure and that the scope of the present invention is to be determined by the following claims.

What is claimed is:

1. A solar-cell module comprising:
a first solar cell having a first energy bandgap;
a second solar cell having a second energy bandgap, the second solar cell being electrically coupled with the first solar cell; and
a controller that is operably coupled with the first solar cell and the second solar cell such that the controller is operative for controlling an electrical parameter of at least one of the first solar cell and the second solar cell, the electrical parameter being at least one of current, voltage, and power;
wherein the first solar cell and second solar cell are arranged such that (1) the first solar cell is operative for absorbing a first portion of a first light signal and passing a second portion of the first light signal to the second solar cell and (2) the second solar cell is operative for absorbing the second portion of the first light signal.

2. The module of claim 1 wherein the first solar cell and second solar cell are electrically connected in series.

3. The module of claim 1 wherein the first solar cell and second solar cell are electrically connected in parallel.

4. The module of claim 1 wherein the controller is operative for controlling the current through only one of the first solar cell and the second solar cell.

5. The module of claim 1 wherein the controller is operative for controlling the current through the first solar cell and for controlling the current through the second solar cell.

6. The module of claim 1 wherein the controller is operative for controlling the output voltage of only one of the first solar cell and the second solar cell.

7. The module of claim 1 wherein the controller is operative for controlling the output voltage of each of the first solar cell and the second solar cell.

8. The module of claim 1 wherein the controller is operative for both increasing and decreasing the magnitude of the electrical parameter.

9. The module of claim 1 wherein the controller is further operable for disabling the module when the electrical parameter exceeds a first threshold.

10. The module of claim 1 wherein the first solar cell is a perovskite-based solar cell.

11. The module of claim 10 wherein the first solar cell is a metal-halide perovskite-based solar cell.

12. The module of claim 10 wherein the second solar cell is a silicon-based solar cell.

13. The module of claim 10 wherein the second solar cell comprises a material selected from the group consisting of copper indium gallium selenide, a II-VI compound semiconductor, a III-V compound semiconductor, and a silicon compound.

14. The module of claim 1 further comprising:
a first plurality of solar cells that includes the first solar cell, wherein each solar cell of the first plurality thereof has the first energy bandgap, and wherein solar cells of the first plurality thereof are electrically connected to collectively define a first solar cell array; and
a second plurality of solar cells that includes the second solar cell, wherein each solar cell of the second plurality thereof has the second energy bandgap, and wherein solar cells of the second plurality thereof are electrically connected to collectively define a second solar cell array;
wherein the controller is operably coupled with the first solar cell array and the second solar cell array such that the controller is operative for controlling the electrical parameter of each solar cell of at least one of the first solar cell array and the second solar cell array.

15. A solar-cell module comprising:
a first solar cell comprising a metal-halide perovskite;
a second solar cell comprising silicon; and
a controller that is that is operative for equalizing an electrical parameter of the first solar cell and the second solar cell, the electrical parameter being at least one of current, voltage, and power;
wherein the first solar cell and second solar cell are arranged such that (1) the first solar cell is operative for absorbing a first portion of a first light signal and passing a second portion of the first light signal to the second solar cell and (2) the second solar cell is operative for absorbing the second portion of the first light signal.

16. The module of claim 15 wherein the controller is a DC-DC converter.

17. The module of claim 15 wherein the controller controls a first current in the second solar cell such that the first current is substantially equal to a second current in the first solar cell.

18. A method for controlling an electrical parameter of a first solar cell having a first electrical bandgap and a second solar cell having a second electrical bandgap, wherein the first solar cell and second solar cell collectively define a tandem solar cell, the method comprising:
providing the tandem solar cell such that (1) the first solar cell is operative for absorbing a first portion of a first light signal and passing a second portion of the first light signal to the second solar cell and (2) the second solar cell is operative for absorbing the second portion of the first light signal;
providing a controller than is operatively coupled with the tandem solar cell;
measuring a first electrical parameter of the tandem solar cell, wherein the first electrical parameter is selected from the group consisting of current, voltage, and power; and
controlling a second electrical parameter of at least one of the first solar cell and the second solar cell based on the measured first electrical parameter, wherein the second electrical parameter is selected from the group consisting of current, voltage, and power.

19. The method of claim 18, wherein the second electrical parameter is controlled by operations comprising:
applying a first electrical signal to the tandem solar cell, wherein the first electrical signal is characterized by a first duty cycle;
determining a first value for the first parameter of the tandem solar cell;
applying a second electrical signal to the tandem solar cell, wherein the second electrical signal is characterized by a second duty cycle;
determining a second value for the first parameter of the tandem solar cell; and
applying a third electrical signal to the tandem solar cell, wherein the third electrical signal is characterized by a third duty cycle that is based on a first difference between the first value and the second value.

20. The method of claim 18, wherein the second electrical parameter is controlled by operations comprising:
applying a first electrical signal to the tandem solar cell, wherein the first electrical signal is characterized by a first duty cycle;
determining a first power output of the first solar cell;
determining a second power output of the second solar cell;
applying a second electrical signal to the tandem solar cell, wherein the second electrical signal is characterized by a second duty cycle;
determining a third power output of the first solar cell;
determining a fourth power output of the second solar cell; and
applying a third electrical signal to the tandem solar cell, wherein the third electrical signal is characterized by a third duty cycle that is based on at least one of a first difference between the first power output and the second third power output and a second difference between the second power output and the fourth power output.
